(19) United States
(12) Patent Application Publication
(10) Pub. No.: US 2020/0194610 A1
(43) Pub. Date: Jun. 18, 2020

(54) LIGHT-OUTPUT-POWER SELF-AWARENESS LIGHT-EMITTING DEVICE

(71) Applicant: BOLB INC., SAN JOSE, CA (US)

(72) Inventors: YING GAO, SAN JOSE, CA (US); LING ZHOU, SAN JOSE, CA (US); ALEXANDER V. LUNEV, SAN JOSE, CA (US); JIANPING ZHANG, SAN JOSE, CA (US)

(21) Appl. No.: 16/224,549

(22) Filed: Dec. 18, 2018

(51) Int. Cl. H01L 31/12; H01L 31/173; H01L 31/0304; H01L 31/0224

(52) U.S. Cl. CPC H01L 31/125; H01L 31/022408; H01L 31/03048; H01L 31/173

(57) ABSTRACT

A light emitting device includes an n-type AlGaN structure, a p-type AlGaN structure, and a light-emitting active-region sandwiched between the n-type AlGaN structure and the p-type AlGaN structure. A first p-contact is formed on the p-type AlGaN structure defining a light-emitting structure, a second p-contact is formed on the p-type AlGaN structure defining a light-detecting structure, and an n-contact is formed on the n-type AlGaN structure serving as a common cathode for the light-emitting structure and the light-detecting structure. There is a bridge zone between the first and the second p-contacts and the p-type AlGaN structure in the bridge zone is not removed.

### FIELD OF THE INVENTION

The present invention relates in general to semiconductor light emitting technology and, more particularly, to a light-emitting device, such as a group III nitride ultraviolet light-emitting diode, with light-output-power self-awareness when in operation.

### DESCRIPTION OF THE RELATED ART

Deep ultraviolet (DUV) emissions (200-280 nm) owing to germicidal effect hold solutions to a number of challenging problems facing humanity, e.g., the increasing scarcity of clean water, overuse of antibiotics, and drug-resistance of pathogens, etc. Traditional DUV light sources involving toxic chemical mercury are to be replaced by environment-friendly, solid-state DUV light sources such as AlGaN-based light-emitting diodes (LEDs).

UV emissions, unlike visible light, are not perceptible by human naked eyes. A direct visual readout of the UV output power on chip-level is highly desired for at least the following reasons. First, a successful disinfection of pathogen necessarily requires sufficient DUV irradiation dosage, which differs for different pathogens. Since dosage is the product of UV irradiance and irradiation duration, it is important to real-time monitor the UV emission power or irradiance level to have a reliable disinfection treatment. Second, UV light sources, including AlGaN-based UV LEDs, usually subject to output power decay as the light sources age. To retain a preset constant output power is desired during the life span of a UV light source for various applications.

In general, a separate photodetector can be used to measure the light source power and, with help of a feedback circuit, constant output power can be maintained, for example, according to the teachings given by U.S. Pat. No. 4,190,795. Even better, a photodetector (PD) and an LED can be integrated in one chip, making a monolithic optocoupler so as to monitor the LED's output power, as disclosed by US patent application publication US20130299841, and U.S. Pat. Nos. 5,753,928 and 9,685,577. The contents of these patents and patent applications are incorporated herein by reference in their entirety.

The present invention provides a light-emitting device and module, without incorporation of an external photodetector, being aware of self's optical light-output power.

### SUMMARY

A light emitting device, such as a light emitting triode (LET), with on-chip optical power readout is provided. The LET contains an n-type semiconductor structure, a light-emitting active-region, and a p-type semiconductor structure. A first and a second p-contacts (anodes) are formed on the p-type semiconductor structure and a common n-contact formed on the n-type semiconductor structure. With respect to the common n-contact, the first p-contact and the second p-contact define a light-emitting structure and a light-detecting structure, respectively. There is a median connecting the first and the second p-contacts. The median may include two portions. The first portion is a bridge zone where the p-type semiconductor structure remains substantially intact and directly connects to the first and the second p-contacts (in other words, the portion of p-type semiconductor structure in the bridge zone is not removed). The second portion is an n-contact zone where the p-type semiconductor structure and light-emitting active-region are removed so that part of n-type semiconductor structure is exposed and part of the n-contact is formed on the exposed n-type semiconductor structure. In operation, holes and electrons are respectively injected into the light-emitting structure through the first p-contact and the common cathode to generate light, while the light-detecting structure defined by the second p-contact and the common n-contact receives part of the generated light and produces photocurrent flowing through a load resistance connected between the second p-contact and the common n-contact (i.e., the load resistance and the light-detecting structure are electrically connected in parallel). The voltage drop measured on the load resistance is configured to be substantially in linear correlation to the light output power of the light-emitting structure of the LET.

A light emitting device is provided which includes:

an n-type AlGaN structure, a p-type AlGaN structure, and a light-emitting active-region sandwiched between the n-type AlGaN structure and the p-type AlGaN structure;

a first p-contact formed on the p-type AlGaN structure defining a light-emitting structure;

a second p-contact formed on the p-type AlGaN structure defining a light-detecting structure; and

an n-contact formed on the n-type AlGaN structure serving as a common cathode for the light-emitting structure and the light-detecting structure;

wherein there is a bridge zone between the first and the second p-contacts and the p-type AlGaN structure in the bridge zone is not removed.

Also provided is a light emitting device including:

an n-type AlGaN structure, a p-type AlGaN structure, and a light-emitting active-region sandwiched between the n-type AlGaN structure and the p-type AlGaN structure;

a first p-contact formed on the p-type AlGaN structure defining a light-emitting structure;

a second p-contact formed on the p-type AlGaN structure defining a light-detecting structure; and

an n-contact formed on the n-type AlGaN structure serving as a common cathode for the light-emitting structure and the light-detecting structure;

wherein there is an n-contact zone between the first and the second p-contacts, the p-type AlGaN structure and the light-emitting active-region in the n-contact zone are removed to expose the n-type AlGaN structure, a portion of the n-contact is formed on the exposed n-type AlGaN structure and a dielectric layer is formed on the portion of the n-contact.

### BRIEF DESCRIPTION OF THE DRAWINGS

The accompanying drawings, which are included to provide a further understanding of the invention and constitute a part of this application, illustrate embodiments of the invention and together with the description serve to explain the principle of the invention. Like reference numbers in the figures refer to like elements throughout, and a layer can refer to a group of layers associated with the same function.

FIG. 1A shows a schematic layered structure of a DUV light-emitting triode (LET) according to an embodiment of the present invention.

FIG. 1B illustrates an equivalent circuit for the LET shown in FIG. 1A to be self-awareness of its light-output-power (LOP), via measuring the voltage drop on a load resistance (R_{L}) connected between the light-detecting anode and the common cathode of the LET.

FIG. 1C shows a schematic layered structure of a DUV light-emitting triode (LET) according to an embodiment of the present invention.

FIGS. 2A-2G show plan views of different DUV LETS according to embodiments of the present invention.

FIG. 3 plots the Pearson correlation coefficients for V_{PD} and LOP, V_{PD} and V_{F} (LET's forward biasing voltage).

FIG. 4 plots the relationship of the voltage of the light-detecting anode (V_{PD}) to the light-output power of a LET made according to FIG. 1A, with different load resistance (R_{L}) connected between the light-detecting anode and the common cathode.

FIG. 5A shows plan view of one DUV LET according to another embodiment of the present invention.

FIG. 5B illustrates the cross-sectional view along AA′ cut of the DUV LET shown in FIG. 5A.

FIG. 6A shows plan view of one DUV LET according to another embodiment of the present invention.

FIG. 6B illustrates the cross-sectional view along AA′ cut of the DUV LET shown in FIG. 6A.

### DETAILED DESCRIPTION OF EMBODIMENTS

Throughout the specification, the embodiments are disclosed for group III nitride light-emitting devices. The teachings can also be extended to light-emitting devices made of other materials. The term group III nitride in general refers to metal nitride with cations selected from group IIIA of the periodic table of the elements. That is to say, group III-nitride includes AlN, GaN, InN and their ternary (AlGaN, InGaN, InAlN) and quaternary (AlInGaN) alloys. In this disclosure, a quaternary can be reduced to a ternary for simplicity if one of the group III elements is significantly small so that its existence does not affect the intended function of a layer made of such material. For example, if the In-composition in a quaternary AlInGaN is significantly small, smaller than 1%, then this AlInGaN quaternary can be shown as ternary AlGaN for simplicity. Using the same logic, a ternary can be reduced to a binary for simplicity if one of the group III elements is significantly small. For example, if the In-composition in a ternary InGaN is significantly small, smaller than 1%, then this InGaN ternary can be shown as binary GaN for simplicity. Group III nitride may also include small amount of transition metal nitride such as TiN, ZrN, HfN with molar fraction not larger than 10%. For example, group III-nitride or nitride may include AlₓIn_{y}Ga_{z}Ti_{(1-x-y-z)}N, AlₓIn_{y}Ga_{z}Zr_{(1-x-y-z)}N, AlₓIn_{y}Ga_{z}Hf_{(1-x-y-z)}N, with (1−x−y−z)≤10%.

As well known, light emitting devices such as light emitting diodes (LEDs) and laser diodes, commonly adopt a laminate structure containing a multiple-quantum-well (MQW) light-emitting active-region, an n-type semiconductor structure for injecting electrons into the active-region, and a p-type semiconductor structure on the other side of the active-region for injecting holes into the active-region.

Embodiments of the present invention provide a light emitting device or a light-emitting triode (LET), with two anodes and a common cathode. The LET contains a light-emitting diode (LED) and a light-detection diode (LDD), and the LED and the LDD share a common cathode. The LDD outputs a photovoltage, V_{PD}, which can be in linear correlation to the light-out-put power (LOP) of the LED. In the LET, the LED and the LDD are formed adjacent to each other on the same substrate of a device chip, and a portion of the light emitted from the LED is transmitted to the LDD through the substrate, the n-type structure, the active-region and the p-type structure of the device chip. The LED and the LDD have their own respective anodes but share a common cathode, formed on the n-type structure of the device. The two anodes can be electrically isolated from each other, for example, by an insulation zone formed via ion implantation into the p-type structure, the active-region and part of the n-type structure in-between the two anodes. According to another aspect of the present invention, the two anodes of the LET can be in electrical connection through a large resistance formed by the p-type structure in-between the two anodes. The LED and the LDD of the LET have exactly the same epitaxial structure and metallic contact structure. The LET can be of any conventional LED or laser diode epitaxial structure.

Optionally, multiple LEDs and/or multiple LDDs can be formed on the same chip, for example, via the process described above. For example, one LED and multiple LDDs, or multiple LEDs and one LDD, or multiple LEDs and multiple LDDs can be formed on one chip. Each of the LEDs and each of the LDDs share a common cathode (n-electrode) while having its own respective anode (p-electrode). The LEDs and the LDDs can also be electrically isolated from each by ion implantation, or be electrically connected by a large resistance formed by the p-type structure there in-between.

In the following, descriptions have been made taking an AlGaN based DUV LET as an example, a person skilled in the art will appreciate that the principles and structures described below can be applied to other light emitting device such as laser diodes and to other wavelength LEDs.

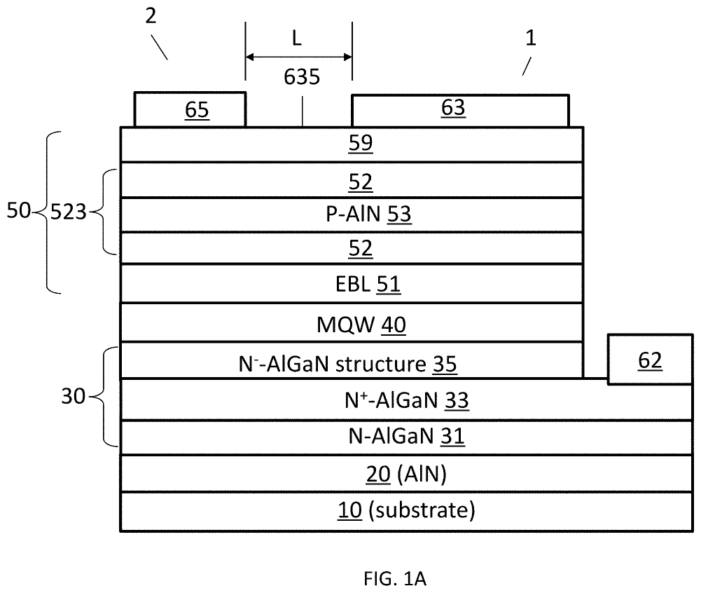

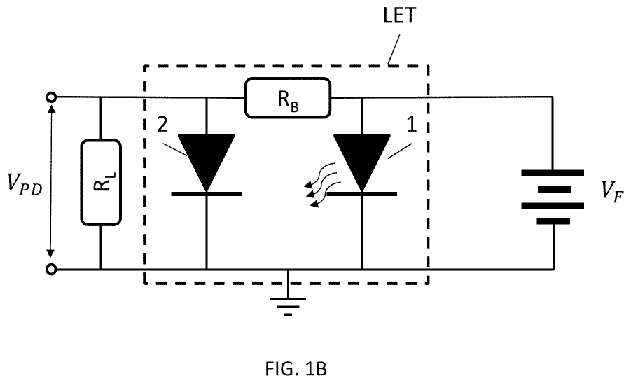

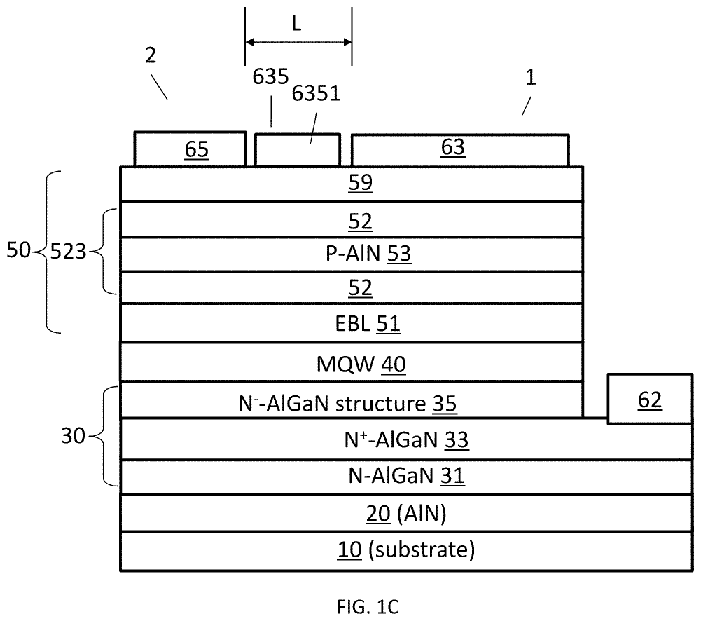

Illustration in FIG. 1A shows the schematic layered structure of a DUV LET with optical power readout according to an embodiment of the present invention. The structure includes a UV transparent substrate 10. Substrate 10 can be selected from sapphire, AlN, SiC, and the like. Formed on substrate 10 is a template 20, which can be made of a thick AlN or high-Al-content AlGaN layer, for example, with a thickness of 0.3-4.0 μm and Al composition in the range of 60-100%. Even though not shown in FIG. 1A, a strain management structure such as an Al-composition grading AlGaN layer or a set of AlN/AlGaN superlattice can be formed on template 20. Formed over template 20 is a thick n-type AlGaN structure 30 for electron supply and n-type ohmic contact formation. Structure 30 may be of any n-type AlGaN structure adopted in a conventional LED. Optionally, structure 30 may include a thick n-type N—AlGaN layer 31 (for example, with a thickness of 2.0-5.0 μm such as 3.0 μm, n=2.0×10¹⁸-5.0×10¹⁸ cm⁻³) for current spreading, a heavily n-type doped N⁺—AlGaN layer 33 (for example, with a thickness of 0.2-0.5 μm such as 0.30 μm, n=8×10¹⁸-2×10¹⁹ cm⁻³) for MQW active-region polarization field screening, and a lightly n-type doped N⁺—AlGaN layer 35 (for example, with a thickness of 0.1-0.5 μm such as 0.15 μm, n=2.5×10¹⁷-2×10¹⁸ cm³) to reduce current crowding and prepare uniform current injection into the following Al_{b}Ga_{1-b}N/Al_{w}Ga_{1-w}N MQW active-region 40. Layer 33 is sandwiched between layer 31 and 35 with layer 35 facing MQW active-region 40. MQW active-region 40 can be any active-region adopted in a conventional LED. In an embodiment, MQW active-region 40 is made of alternately stacked n-Al_{b}Ga_{1-b}N barrier and Al_{w}Ga_{1-w}N well for a few times, for example, for 3-8 times. The thickness of a single barrier is in the range of 6.0-16.0 nm, and the thickness of a single well is 1.0-5.0 nm. The total thickness of MQW active-region 40 can be less than 200 nm, for example, being 75 nm, 100 nm, or 150 nm. The n-Al_{b}Ga_{1-b}N barrier and Al_{w}Ga_{1-w}N well may have an Al-composition in the range of 0.3-1.0 and 0.0-0.85, respectively, and the Al-composition difference of the barrier and well is at least 0.15 (b−w>0.15) to ensure a barrier-well bandgap width difference (ΔE_{g}) at least 400 meV to secure quantum confinement effect. Following MQW active-region 40 is a p-type AlGaN structure 50, which in general can be of any layered p-type structure adopted in a conventional LED. Optionally, the part of p-type AlGaN structure 50 in contact with MQW active-region 40 is a hole injecting and electron blocking layer (EBL) 51 which can be a p-AlGaN layer or a p-AlGaN superlattice structure, or a p-AlGaN multilayer structure. Following EBL 51 can be a hole spreading structure 523 including a p-type Mg-doped AlGaN or GaN channel 52 and a p-type AlN barrier 53. Barrier 53 and channel 52 form a two-dimensional hole gas in channel 52 for lateral current spreading. The Al composition in channel 52 can be small, or vanishing, for example, the Al composition of channel 52 can be in the range of 0 to 0.1 (10%), or 0 to 0.05 (5%). And the thicknesses of barrier 53 and channel 52 can be 1-3 nm and 0.5-1.5 nm, respectively. Further, barrier 53 and channel 52 can be alternately formed for a few times, for example, 1-8 times, or 3-7 times, but always with a layer of channel 52 contacting EBL 51 and another layer of channel 52 contacting a hole supplier and p-contact layer 59. In other words, if there are m layers of barrier 53, there would be m+1 layers of channel 52, where m is an integer and can be in the range of 1-8. The total thickness of p-type AlGaN structure 50 can be less than 300 nm, for example, being 50 nm, 70, nm or 110 nm. Hole supplier and p-contact layer 59 can be heavily doped with Mg, to a concentration above 10²⁰ cm⁻³, for example, from 1.0×10²⁰ cm⁻³ to 1.0×10²¹ cm⁻³, or from 2.0×10²⁰ cm⁻³ to 6.0×10²⁰ cm⁻³. Hole supplier and p-contact layer 59 can be made of p-type InN, InGaN, GaN, AlGaN, or AlN with a thickness in the range of 0.52-10 nm.

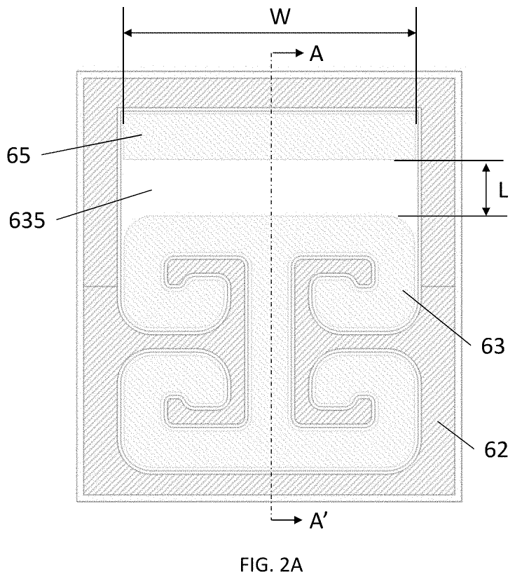

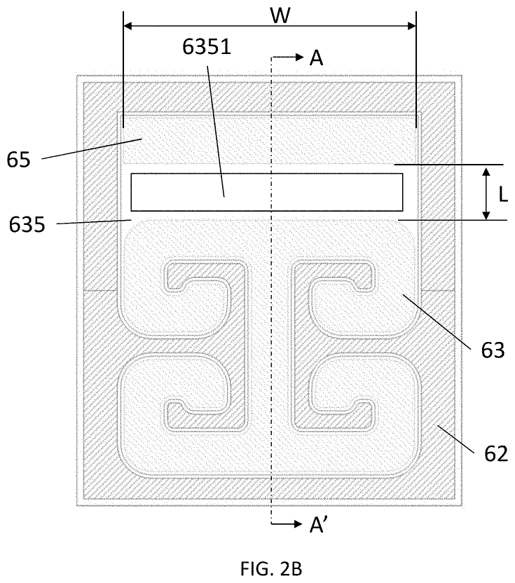

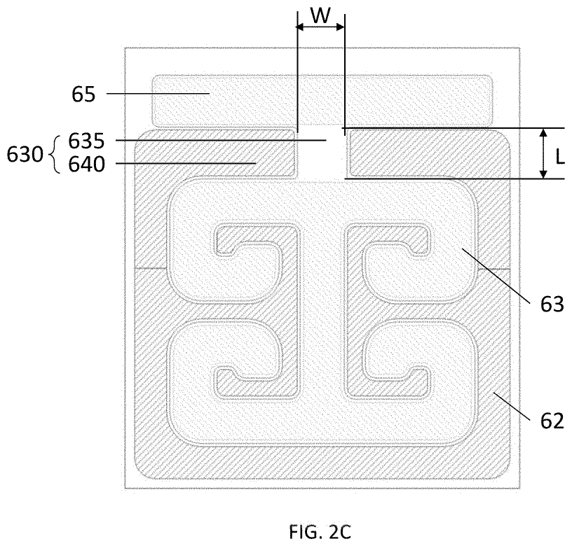

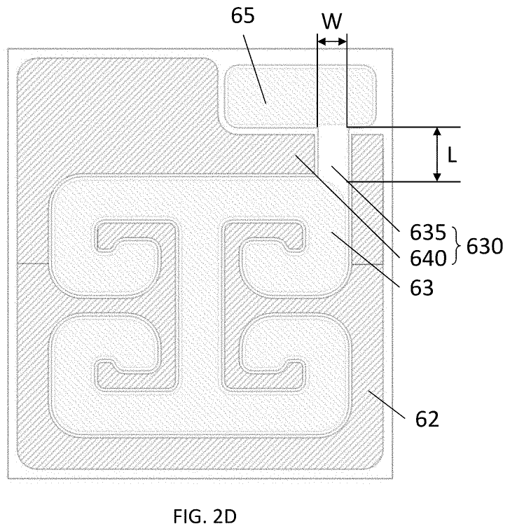

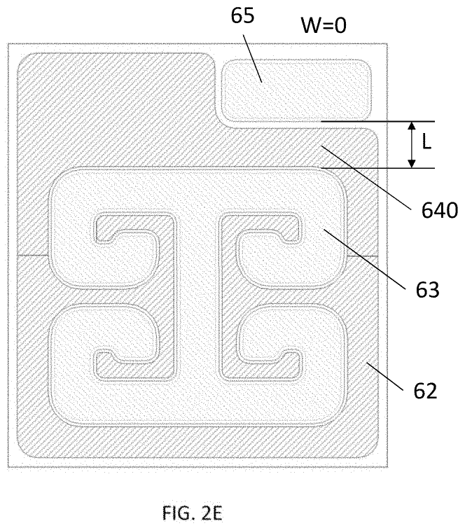

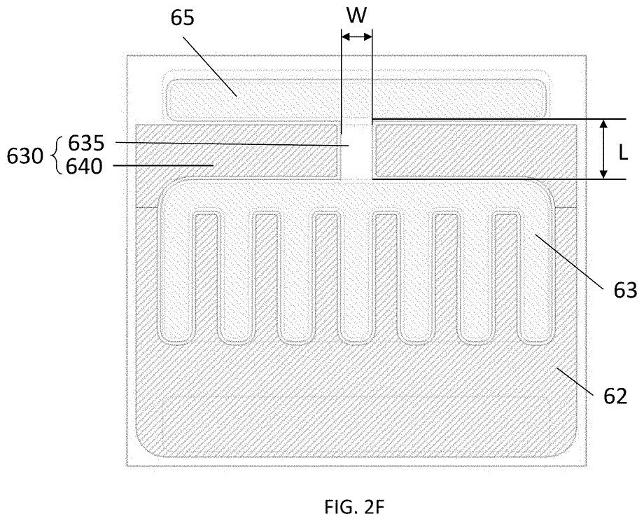

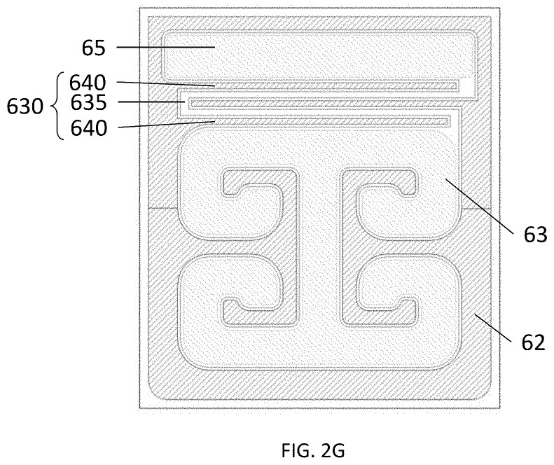

For electrical injection, n-contact 62 is formed on N⁺—AlGaN layer 33 serving as common cathode, and p-contacts 63 and 65 are formed on hole supplier and p-contact layer 59, serving as anodes respectively for LED 1 and LDD 2 of the LET. LED 1 refers to the structure substantially covered by p-contact 63 and LDD 2 refers to the structure substantially covered by p-contact 65. Between p-contacts 63 and 65, there is a median 630 connecting p-contacts 63 and 65 (refer to FIGS. 2A-2G, 5A, 6A). Median 630 may include two portions, the first portion is a bridge zone 635 where p-type AlGaN structure 50 remains substantially intact and directly connects to p-contacts 63 and 65 (in other words, the portion of p-type AlGaN structure 50 in bridge zone 635 is not removed), the second portion is an n-contact zone 640 where p-type AlGaN structure 50 and MQW active-region 40 are removed so that part of n-type AlGaN structure 30 is exposed and part of n-contact 62 is formed on the exposed n-type AlGaN structure 30. In an embodiment, for example, the one shown in FIGS. 1A and 2A where FIG. 1A illustrates a cross-sectional view along AA′ cut of FIG. 2A, no UV reflective layer is formed on hole supplier and p-contact layer 59 in bridge zone 635. In another embodiment, for example, the one shown in FIGS. 1C and 2B where FIG. 1C illustrates a cross-sectional view along AA′ cut of FIG. 2B, there may have a UV reflective layer 6351 formed on bridge zone 635. Layer 6351 can be a UV reflective single layer made of a single SiO₂, CaF₂, MgF₂, Al, Rh, et al layer, or a UV reflective multiple-layer structure made from SiO₂, CaF₂, MgF₂, Al, Rh et al. When layer 6351 is a single UV reflective metal layer, for example, metal Al or Rh layer, or Ni—Mg alloy being formed on hole supplier and p-contact layer 59 to reflect UV light, layer 6351 does not provide electrical connection to p-contacts 63 and 65 (refer to FIGS. 1C, 2B). Layer 6351 made of UV reflective metal can connect to each of the p-contacts 63 or 65, but cannot connect to both of them simultaneously. This means that p-contacts 63 and 65 are spaced apart from each other by a bridge zone 635 whose lateral distance is labeled as L in FIG. 1A. In general, median 630 can be filled with a dielectric material (optionally UV-transparent, such as silicon dioxide et al) on the n-contact 62 in n-contact zone 640 and on the p-type AlGaN structure 50 in bridge zone 635.

As shown in FIG. 1A, the light-emitting structure of LED 1 is substantially defined by p-contact 63 and the light-detecting structure of LDD 2 is substantially defined by p-contact 65. This is achievable since sheet resistance of p-type AlGaN structure 50 used in DUV LED/LET is very large (>10⁵Ω/□, even >10′⁷Ω/□), so there is negligible current spreading length beyond p-contacts. If sheet resistance of p-type AlGaN structure 50 is small, such as smaller than 10⁵Ω/□, ion-implantation can be applied to bridge zone 635, to make the sheet resistance of the bridge zone high enough, such as larger than 10⁵, 10⁶, or 10⁷Ω/□. The ion-implantation for electrical insulation can be achieved via high energy high dosage H⁺, He⁺, and Ar⁺ implantation. The ratio between the area covered by p-contact 63 and the area covered by p-contact 65 can be determined according to the desired performance of the LET and usually can be in the range of 5-50, for example, 7-20.

FIG. 1B illustrates an equivalent circuit for the LET shown in FIG. 1A in operation. As seen, LED 1 and LDD 2 of the LET share a common cathode, and their anodes are connected via a bridge zone resistance, R_{B}, which is determined by sheet resistance of the p-type AlGaN structure 50 and the geometry of the bridge zone 635. A load resistance, R_{L}, is connected in parallel to LDD 2 between the common cathode and the anode of LDD 2. When the LET is in operation, light emitted by LED 1 can be transmitted to LDD 2, via substrate 10, template 20, n-type AlGaN structure 30, MQW active-region 40 and p-type AlGaN structure 50. LDD 2 receives the light emission and produces photocurrent through the shunted load resistance R_{L}. Self-awareness of the LET's light-output-power (LOP) can be realized via measuring the voltage drop (V_{PD}) on R_{L}. V_{PD} can be calculated according to eq. 1:

$${V}_{PD} = {R}_{L} {I}_{ph} + {V}_{F} \frac{{R}_{L}}{{R}_{L} + {R}_{B}} \qquad ( eq . 1 )$$

where V_{F}, Iₚₕ are LED 1's forward bias voltage and LDD 2's photocurrent, respectively. Eq. 1 is valid when R_{B}>R_{L} so that

$${V}_{F} \frac{{R}_{L}}{{R}_{L} + {R}_{B}}$$

is far less than the turn-on threshold voltage of LDD 2. It is noted that before the turn-on threshold LDD 2 possesses infinitely large resistance. In reality an LED before turn-on threshold voltage can have resistance larger than 1 GΩ. An ideal LED structure (e.g. LDD 2) is a rectifying device, can have infinite large resistance (so no current flow) before turn-on threshold voltage. When

$${V}_{F} \frac{{R}_{L}}{{R}_{L} + {R}_{B}}$$

is far less than the turn-on threshold voltage of LDD 2, LDD 2 in the equivalent circuit can be viewed as a current source with very large input impedance, and eq. 1 holds. If

$${V}_{F} \frac{{R}_{L}}{{R}_{L} + {R}_{B}}$$

is larger than LDD 2's turn-on threshold voltage, LDD 2's resistance greatly reduces, therefore eq. 1 no longer holds. Also, from eq. 1, when R_{B} is sufficiently large (approaching infinity), V_{PD} is in linear relationship to Iₚₕ, which in turn is in linear relationship to LED 1's light-output-power (LOP).

The following embodiments illustrate how to design bridge zone 635 and select load resistance R_{L} to make V_{PD} substantially in linear relationship with LOP of the LED 1 in an LET such as the LET shown in FIG. 1A. For this purpose, shown in FIGS. 2A-2G are plan views of seven different DUV LETs according to embodiments of the present invention. A cross-sectional view along AA′ cut of FIG. 2A can be as shown in FIG. 1A. In embodiments shown in FIGS. 2A-2F, bridge zones 635 have a substantially rectangular shape with width W and length L, where L is the distance between the opposing edges of p-contacts 63 and 65, W is the width which entirely falls in the area where the opposing edges of p-contacts 63 and 65 face each other. The bridge zone resistance, R_{B}, for a rectangular bridge zone 635 is calculated according to eq. 2.

$${R}_{B} = {ρ}_{p} \frac{L}{{t}_{p} W} = {R}_{p \text{-} sh} \frac{L}{W} \qquad ( eq . 2 )$$

where ρₚ, tₚ and Rₚ₋ₛₕ are the resistivity, thickness and sheet resistance of p-type AlGaN structure 50, respectively. The sheet resistance of p-type AlGaN structure 50 used in DUV LED/LET is usually very large, larger than 10⁵Ω/□, or even larger than 10⁷Ω/□. For a given LED epi-wafer, designs of R_{B} can be determined by selections of width W and length L of the bridge zone 635 according to eq. 2. The width W of the bridge zone 635 can be in the range of zero (e.g., Win FIG. 2E) to the width of the light-emitting mesa (e.g., Win FIG. 2A) of the LED 1, for example, from 10-1000, 50-500, or 100-300 μm. In other words, width W can be 0-100% of the width of p-contact 65 facing p-contact 63, such as 10%, 30%, 50%, or 70%. When W=0, as shown in the embodiment given by FIG. 2E, the LDD 2 and the LED 1 are connected via R_{B}=∞ (i.e., the p-type AlGaN structure 50 and MQW active-region 40 are removed and n-contact 62 is formed in the entire median 630). The length L of the bridge zone 635 can be in the range of a few tens of microns to a few hundreds of microns, for example, from 50-200, or 100-150 microns. As a result, bridge zone R_{B} can be in the range of a few mega ohms (MΩ) to infinity, for example, 1-500, 20-450, or 50-100 MΩ.

In some embodiments, bridge zone 635 may have other shapes such as curved, spiral or wave-like shapes as shown in FIG. 2G. R_{B} can be adjusted by adjusting the shape of bridge zone 635.

If the sheet resistance of p-type AlGaN structure 50 is small, for example smaller than 10⁵Ω/□ (e.g., in the range of 10⁴Ω/□-10⁵Ω/□), for cases of longer wavelengths LEDs such as visible or infrared LEDs, then the length L of bridge zone 635 can be significantly larger, for example 2-3 orders of magnitudes larger than its width W, as shown in the embodiment illustrated in FIG. 2G. Or using a design by selecting the width W equal to zero, as illustrated in FIG. 2E.

As can be seen, the p-contact 65 in the LET shown in FIGS. 2A and 2B is of a rectangular shape and has a width substantially the same as that of the p-contact 63. P-contact 63 is of a symmetrical shape similar to two connected “T” with two arms of the “T” downwardly and inwardly bended. The p-contacts 65 in the LETs shown in FIGS. 2D and 2E are of a rounded corner rectangular shape and have a width smaller than (for example, half of) that of the p-contact 63. The p-contact 65 in the LET shown in FIG. 2F is of a rectangular shape and has a width substantially the same as that of the p-contact 63. P-contact 63 is of a shape of comb with the fingers pointing away from n-contact 65. The p-contact 65 and p-contact 63 in the LET shown in FIG. 2G have a shape similar to that of FIG. 2A.

In the plan views of LETs of embodiments shown in FIGS. 2A-2G, n-contact 62 plus median 630 may completely encircle p-contact 63. In some embodiments, n-contact 62 may completely encircle both p-contact 63 and p-contact 65.

Optionally, median 630 may further include a third portion of insulation zone where p-type AlGaN structure 50 is removed, MQW active-region 40 may or may not be removed, but no n-contact is formed in the insulation zone. The insulation zone is filled with a dielectric material.

A UV reflective layer 6351 can be formed on bridge zone 635 and electrical insulation is provide between the UV reflective layer and p-contact 63, or between the UV reflective layer and p-contact 65, or between the UV reflective layer, p-contact 63 and p-contact 65 as shown in FIGS. 1C and 2B. The UV reflective layer can be made of metal Aluminum, or Rhodium, or nickel-magnesium alloy.

The following embodiments describe how to select load resistance R_{L} to ensure V_{PD} is in linear or close to linear relationship with LOP. In general, according to eq. 1, V_{PD} increases linearly with Iₚₕ (hence LOP) and V_{F}. Proper load resistance, R_{L}, may satisfy these conditions: 1) V_{PD} is large enough for direct measurement using a simple multimeter; 2) V_{PD} is in strong linear relationship to LOP; and 3) V_{PD} much less correlates to V_{F}. For these purposes, different load resistances are tested to find the Pearson correlation coefficients of V_{PD} to LOP and V_{PD} to V_{F}. Pearson correlation coefficient of two sets of data (X={xᵢ}, Y={yᵢ}) is defined as r according to eq. 3.

$$r = \frac{{\sum }_{i} ( {x}_{i} - \overline{x} ) ( {y}_{i} - \overline{y} )}{\sqrt{{\sum }_{i} {( {x}_{i} - \overline{x} )}^{2}} \sqrt{{\sum }_{i} {( {y}_{i} - \overline{y} )}^{2}}} \qquad ( eq . 3 )$$

where xᵢ, yᵢ are individual sample points indexed with i, x̅ and y̅ are the mean value for the two data sets. The correlation coefficient ranges from −1 to 1. A value of 1 implies that a linear equation describes the relationship between X and Y perfectly, with all data points lying on a line for which Y increases as X increases. A value of −1 implies that all data points lie on a line for which Y decreases as X increases. A value of 0 implies that there is no linear correlation between the variables.

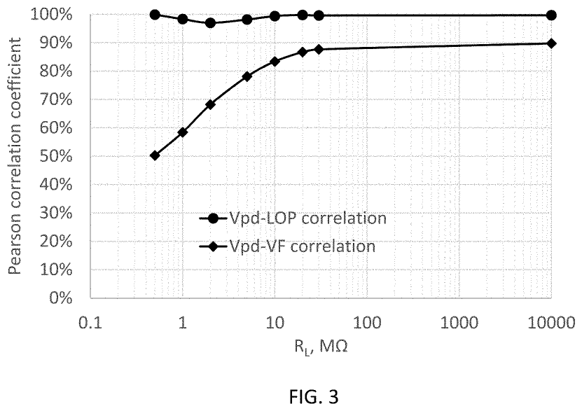

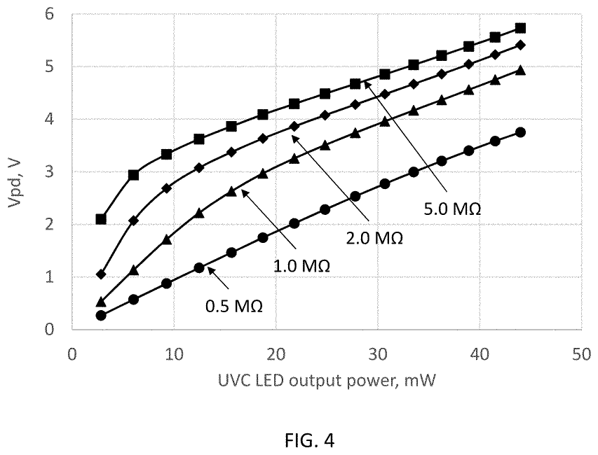

Plotted in FIG. 3 are Pearson correlation coefficients for V_{PD}-LOP and V_{PD}-V_{F} with different load resistance R_{L}, for a DUV LET whose plan view is illustrated in FIG. 2F. It is noted that the relationship between the load resistance and the correlation coefficients can be affected by LET's bridge zone 635, especially by the sheet resistance of p-type AlGaN structure 50 and the width and length of bridge zone 635. For the data shown in FIGS. 3 and 4, the width and length of bridge zone 635 were 10 and 200 microns, respectively. The sheet resistance of the p-type AlGaN 50 was estimated to be 10⁷Ω/□, so the bridge zone resistance, R_{B}, was calculated to be 200 MΩ according to eq. 2. The LET's epitaxial structure is as follows, including a c-plane sapphire substrate 10, a 2.5 μm-thick AlN template 20, a 2.3 μm-thick n-type N-Al_{0.56}Ga_{0.44}N layer 31 (doped with Si, [Si]=n=3.5×10¹⁸ cm⁻³), a 0.25 μm N⁺—AlGaN layer 33 (n=8.2×10¹⁸ cm⁻³), a 0.15 μm N—AlGaN layer 35 (n=5.0×10¹⁷ cm³), an MQW active-region 40 made of 5-pair 12-nm-thick-Al_{0.55}Ga_{0.45}N-barrier/4-nm-thick-Al_{0.4}Ga_{0.6}N-well, a Mg-doped ([Mg]=2.5×10¹⁹ cm⁻³) superlattice (SL) EBL 51 made of 4-pair 6-nm-thick-Al_{0.75}Ga_{0.25}N-barrier/4-nm-thick-Al_{0.6}Ga_{0.4}N-well, a Mg-doped ([Mg]=8.0×10¹⁹ cm⁻³) hole spreading structure 523 including 5 pair 0.5 nm-thick GaN channel 52/1.0 nm-thick AlN barrier 53, and a hole supplier and p-contact layer 59 made of 1.3 nm-thick AlN doped with [Mg]=2.5×10²⁰ cm³.

As seen, for R_{L} ranging from 0.5 MΩ to 10 GΩ, V_{PD}-LOP has very good linear correlation, with r in the range of 0.970 to 0.999. The Pearson correlation coefficient of V_{PD}-V_{F} approaches 0.9 for R_{L} larger than 30 MΩ, but it quickly reduces as R_{L} decreases, dropping to 0.5 for R_{L}=0.5 MΩ. In principal, Pearson correlation coefficient of V_{PD}-V_{F} can approach zero for very small R_{L}, however, this will lead to very small V_{PD} that is not easy to measure using a simple multimeter accessed to general public. Therefore, in some embodiments, the load resistance R_{L} is selected to ensure the V_{PD}-V_{F} Pearson correlation coefficient less than 0.8 (R_{L} is about 6 MΩ at this point in FIG. 3) and the V_{PD}-LOP Pearson correlation coefficient larger than 0.95. To meet these Pearson correlation coefficients requirement, it is noted that large R_{B} usually allows for large R_{L} upper limits. According to the present invention, the load resistance R_{L} is optionally in the range of 0.1-10.0 MΩ. It has been experimentally observed by the inventors that the existence of a bridge zone 635 enhances light coupling from LED 1 to LDD 2 so that stronger V_{PD} can be obtained for measurement convenience.

Some measured V_{PD} data as function of LOP for different load resistance R_{L} are plotted in FIG. 4, for the same DUV LET measured in FIG. 3. As seen, for R_{L}=0.5 MΩ, the V_{PD} data is in linear relationship to the LOP data, with a Pearson coefficient equal to 0.999 (still weakly correlated to V_{F} as the V_{PD}-V_{F} Pearson correlation coefficient is 0.5). The V_{PD} values measured with R_{L}=0.5 MΩ for the LOP ranging from 2.83 mW to 43.99 mW are in the range of 0.27 to 3.75V, easily accessible by a simple multimeter.

The LETs according to the embodiments shown in FIGS. 2A-2G all have common n-contact 62 formed in a substantially two-dimensional plane defined by n-AlGaN structure 30 (optionally by N⁺—AlGaN layer 33). And p-contacts 63 reside in a vertically displaced plane defined by p-AlGaN structure 50, with no intersection with n-contact 62.

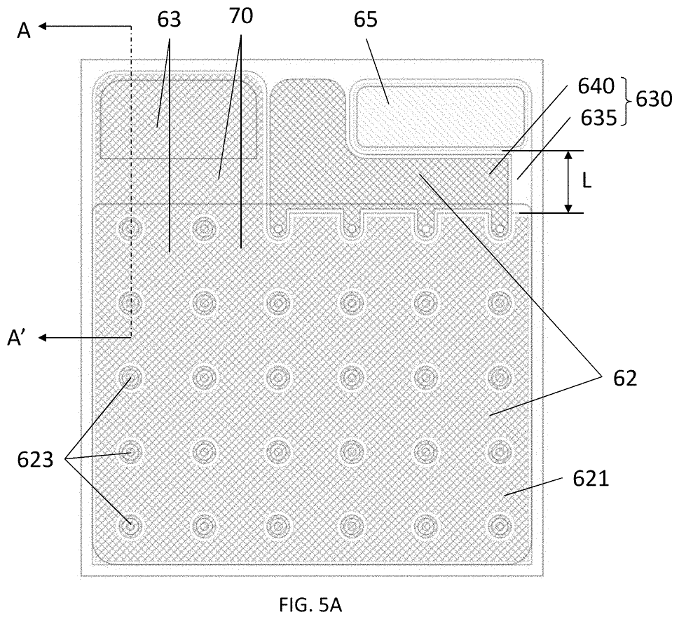

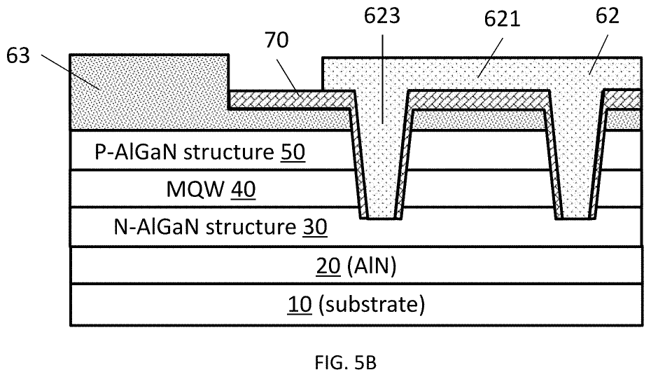

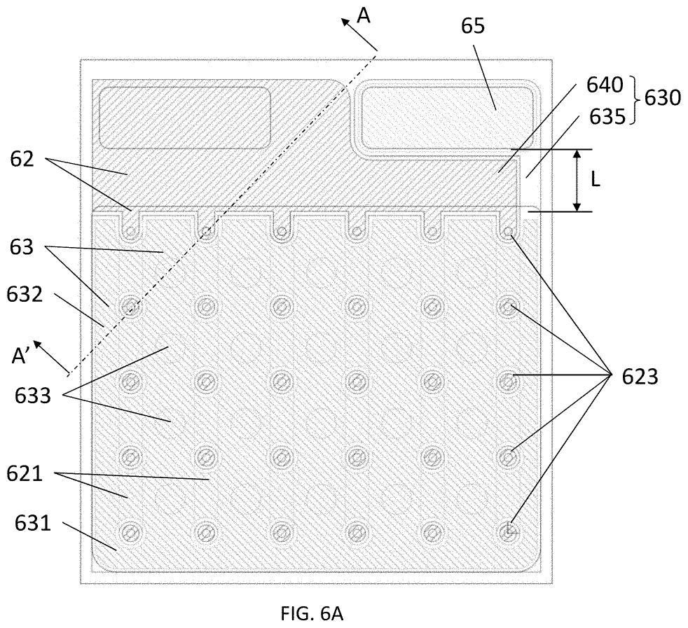

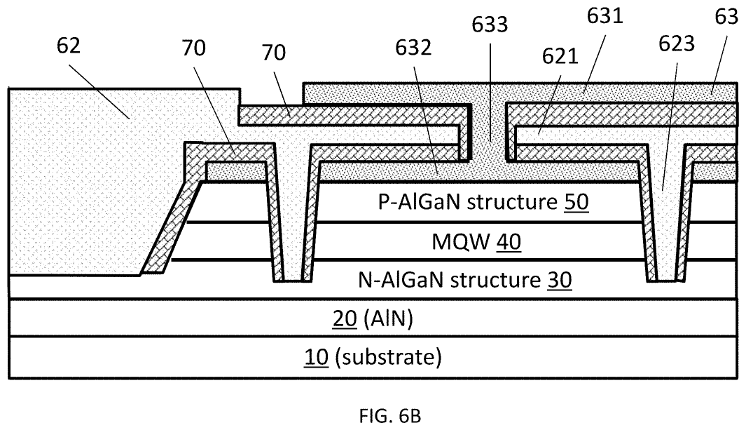

In other embodiments, n-contact 62 may be formed on a plane defined by n-AlGaN structure 30 and have a portion extending vertically from the plane to intersect with p-contact 63. Two such LET embodiments are shown in FIGS. 5A and 6A, with respective cross-sectional view taken from AA′ cut shown in FIGS. 5B and 6B. The cross-sectional views show that at least a portion of n-contact 62, forming crossover pillars 623, crosses over a portion of p-contact 63 in a direction substantially perpendicular to the interface between the p-type AlGaN structure 50 and the light-emitting active-region MQW 40. A dielectric layer 70 is formed around crossover pillars 623 and between n-contact 62 and p-contact 63 underneath thereof to insulate n-contact 62 from p-contact 63. As shown in FIG. 5B, crossover pillars 623 are part of n-contact 62 and extend upwards from n-AlGaN structure 30 crossing over p-contact 63. Connected to the upper ends of crossover pillars 623 is a flat horizontal portion 621 of n-contact 62 which is also separated from underneath p-contact 63 by dielectric layer 70. The exposed portion of p-contact 63 may have an upper surface higher than that of dielectric layer 70 and may be co-plane with the upper surface of the flat horizontal portion 621 of n-contact 62.

Another LET is shown in FIGS. 6A and 6B, which differs from that of FIGS. 5A and 5B in that an additional p-contact layer 631 of p-contact 63 is formed on the flat horizontal portion 621 of n-contact 62. P-contact layer 631 is connected to the underneath p-contact layer 632 (which is formed on p-type AlGaN structure 50) of p-contact 63 via a crossover pillar 633. The above different parts of p-contact are insulated from n-contact 62 via dielectric layer 70.

The application of three-dimensional n-contacts 62 shown in FIGS. 5-6 enlarges light-emitting structure of LEDs 1 in the LETs.

The present invention has been described using exemplary embodiments. However, it is to be understood that the scope of the present invention is not limited to the disclosed embodiments. On the contrary, it is intended to cover various modifications and similar arrangement or equivalents which can be obtained by a person skilled in the art without creative work or undue experimentation. The scope of the claims, therefore, should be accorded the broadest interpretation so as to encompass all such modifications and similar arrangements and equivalents.

1. A light emitting device comprising:
an n-type AlGaN structure, a p-type AlGaN structure, and a light-emitting active-region sandwiched between the n-type AlGaN structure and the p-type AlGaN structure;
a first p-contact formed on the p-type AlGaN structure defining a light-emitting structure;
a second p-contact formed on the p-type AlGaN structure defining a light-detecting structure; and
an n-contact formed on the n-type AlGaN structure serving as a common cathode for the light-emitting structure and the light-detecting structure;
wherein there is a bridge zone between the first and the second p-contacts and the p-type AlGaN structure in the bridge zone is not removed.

2. The light-emitting device according to claim 1, wherein, when in operation, holes and electrons are injected into the light-emitting active-region respectively via the first p-contact and the n-contact for the light-emitting structure to emit light, and a load resistance is connected between the second p-contact and the n-contact in parallel with the light-detecting structure, and a voltage drop on the load resistance corresponds to a light-output power of the light-emitting structure.

3. The light-emitting device according to claim 2, wherein the load resistance is selected to ensure that the voltage drop on the load resistance has a Pearson correlation coefficient to the light-output power of the light-emitting structure larger than 0.95, while the voltage drop on the load resistance has a Pearson correlation coefficient to a forward bias voltage of the light-emitting structure less than 0.8.

4. The light-emitting device according to claim 3, wherein the load resistance is in the range of 0.1-10.0 mega ohm.

5. The light-emitting device according to claim 1, wherein the bridge zone is of a bridge zone resistance larger than 1 mega ohm.

6. The light-emitting device according to claim 1, wherein the bridge zone resistance is larger than 10 mega ohm.

7. The light-emitting device according to claim 1, wherein an additional n-contact is formed on a portion of the first p-contact with a dielectric layer inserted therebetween, the additional n-contact is electrically connected to the n-contact via a crossover pillar penetrating the p-type AlGaN structure and the light-emitting active-region.

8. The light-emitting device according to claim 7, wherein an additional first p-contact is formed on a portion of the additional n-contact with a dielectric layer inserted therebetween, the additional first p-contact is electrically connected to the first p-contact via a crossover pillar penetrating the additional n-contact.

9. The light emitting device according to claim 1, wherein the n-type AlGaN structure comprises an n-type N—AlGaN layer with a thickness of 2.0-5.0 μm and a doping concentration of 2.0×10¹⁸-5.0×10¹⁸ cm⁻³ for current spreading, an n-type N⁺—AlGaN layer with a thickness of 0.2-0.5 μm and a doping concentration of 8×10¹⁸-2×10¹⁹ cm⁻³ for active-region polarization field screening, and an n-type N⁻—AlGaN layer with a thickness of 0.1-0.5 μm and a doping concentration of n=2.5×10¹⁷-2×10¹⁸ cm⁻³ for reducing current crowding and uniform current injection into the light-emitting active-region.

10. The light emitting device according to claim 1, wherein the light-emitting active-region comprises a plurality of alternately stacked n-Al_{b}Ga_{1-b}N barriers and Al_{w}Ga_{1-w}N wells; a thickness of each of the n-Al_{b}Ga_{1-b}N barriers is in the range of 8-16 nm, and a thickness of each of the Al_{w}Ga_{1-w}N wells is 2-5 nm; the n-Al_{b}Ga_{1-b}N barrier and Al_{w}Ga_{1-w}N well have an Al-composition in the range of 0.3-1.0 (b=0.3-1.0) and 0.0-0.85 (w=0.0-0.85), respectively, and the Al-composition difference between the barrier and the well is at least 0.15 (b−w≥0.15).

11. The light emitting device according to claim 1, wherein the p-type AlGaN structure comprises a hole injecting and electron blocking layer, a hole spreading structure, and a hole supplier and p-contact layer.

12. The light emitting device according to claim 11, wherein the hole injecting and electron blocking layer is a p-AlGaN layer, or a p-AlGaN superlattice structure, or a p-AlGaN multilayer structure; the hole spreading structure comprises alternately stacked p-type Mg-doped AlGaN or GaN channel and p-type AlN barrier; and the hole supplier and p-contact layer is made of p-type InN, InGaN, GaN, AlGaN, or AlN.

13. The light-emitting device according to claim 5, wherein ions are implanted into the p-type AlGaN structure and the light-emitting active-region in the bridge zone to increase the bridge zone resistance.

14. The light-emitting device according to claim 1, wherein the first p-contact and the second p-contact are formed on the p-type AlGaN structure side-by-side with a first edge of the first p-contact facing a first edge of the second p-contact, the bridge zone is formed between the first edge of the first p-contact and the first edge of the second p-contact along an entire length of the first edge of the first p-contact and the first edge of the second p-contact, or along a portion of the entire length of the first edge of the first p-contact and the first edge of the second p-contact.

15. The light-emitting device according to claim 1, wherein a UV reflective layer is formed on the bridge zone and electrical insulation is formed between the UV reflective layer and the first p-contact, or between the UV reflective layer and the second p-contact, or between the UV reflective layer, the first p-contact and the second p-contact.

16. The light-emitting device according to claim 15, wherein the UV reflective layer is made of metal Aluminum, or Rhodium, or nickel-magnesium alloy.

17. The light-emitting device according to claim 15, wherein the UV reflective layer is made of SiO₂, CaF₂, MgF₂ single or multiple layers

18. A light emitting device comprising:
an n-type AlGaN structure, a p-type AlGaN structure, and a light-emitting active-region sandwiched between the n-type AlGaN structure and the p-type AlGaN structure;
a first p-contact formed on the p-type AlGaN structure defining a light-emitting structure;
a second p-contact formed on the p-type AlGaN structure defining a light-detecting structure; and
an n-contact formed on the n-type AlGaN structure serving as a common cathode for the light-emitting structure and the light-detecting structure;
wherein there is an n-contact zone between the first and the second p-contacts, the p-type AlGaN structure and the light-emitting active-region in the n-contact zone are removed to expose the n-type AlGaN structure, a portion of the n-contact is formed on the exposed n-type AlGaN structure and a dielectric layer is formed on the portion of the n-contact.
